(19) United States
(12) Patent Application Publication
(10) Pub. No.: US 2025/0183062 A1
(43) Pub. Date: Jun. 5, 2025

(54) APPARATUS FOR HEAT-TREATING SUBSTRATE AND APPARATUS FOR TREATING SUBSTRATE

(71) Applicant: SEMES CO., LTD., Cheonan-si (KR)

(72) Inventors: Kyung Taek IM, Cheonan-si (KR); Seung Jun LEE, Seoul (KR); Su Jin AHN, Suwon-si (KR)

(21) Appl. No.: 18/953,196

(22) Filed: Nov. 20, 2024

(30) Foreign Application Priority Data
Nov. 30, 2023 (KR) 10-2023-0171420

(51) Int. Cl. H01L 21/67; H01L 21/673

(52) U.S. Cl. CPC H01L 21/67103; H01L 21/67167; H01L 21/67393

(57) ABSTRACT

Disclosed is a substrate heat-treating apparatus including: a housing having a first lateral portion and a second lateral portion facing the first lateral portion; a heating unit located adjacent the second lateral portion and including a bake plate heating a substrate; and a capture module installed in the second lateral portion and for capturing fumes contained in gas exhausted from the heating unit.

### CROSS-REFERENCE TO RELATED APPLICATIONS

This application claims priority to and the benefit of Korean Patent Application No. 10-2023-0171420 filed in the Korean Intellectual Property Office on Nov. 30, 2023, the entire contents of which are incorporated herein by reference.

### TECHNICAL FIELD

The present invention relates to an apparatus for heat-treating a substrate, and a substrate treating apparatus.

### BACKGROUND ART

In order to manufacture a semiconductor device, various processes, such as cleaning, deposition, photography, etching, and ion implantation, are performed. Among these processes, an application process is used to form a liquid film on the substrate. In general, the application process is a process of applying a treatment solution onto the substrate to form a liquid film.

Before or after forming a liquid film on the substrate, the substrate may be heat treated in a bake chamber. In the bake chamber, the substrate is placed on a heating plate, and the heating plate heats the substrate while fixing the substrate to be flat by using vacuum.

However, fumes generated during the heat treatment of the substrate are discharged through a vacuum hole formed in the heating plate, and fumes through the vacuum hole can contaminate or cause failure of a bake chamber or auxiliary equipment connected to the bake chamber (e.g., a cooling water supply device or a vacuum pump).

### SUMMARY OF THE INVENTION

The present invention has been made in an effort to provide a substrate heat-treating apparatus mounted on a bake unit and capable of separating fumes from an airflow entering through a vacuum hall, and a substrate treating apparatus including the same.

The present invention has also been made in an effort to provide a substrate heat-treating apparatus in which maintenance and repair of a capture module is easy, and a substrate treating apparatus including the same.

The problem to be solved by the present invention is not limited to the above-mentioned problems, and the problems not mentioned will be clearly understood by those skilled in the art from the descriptions below.

An exemplary embodiment of the present invention provides a substrate heat-treating apparatus including: a housing having a first lateral portion and a second lateral portion facing the first lateral portion; a heating unit located adjacent the second lateral portion and including a bake plate heating a substrate; and a capture module installed in the second lateral portion and for capturing fumes contained in gas exhausted from the heating unit

Further, the bake plate may further include vacuum holes for providing vacuum pressure received through a vacuum pressure line to a bottom surface of the substrate, and the capture module may include: a trap box connected to the vacuum pressure line, and for capturing fumes in gas exhausted through the vacuum pressure line; and a cooling block provided on one surface of the trap box, and the second lateral portion is located opposite a frame cover for maintenance and repair, and the capture module is located between the second lateral portion and the frame cover.

Further, the substrate heat-treating apparatus may further include a cooling unit located within the housing and for cooling the substrate by using a refrigerant, in which the cooling block receives a refrigerant used to cool the substrate in the cooling unit to cool gas passing through the trap box.

Further, the capture module may further include a heat blocking member for blocking cold energy from the cooling block from being transferred to the heating unit.

Further, the heat blocking member may be located between the cooling block and the second lateral portion, and is spaced apart from the second lateral portion, and the second lateral portion may have a recessed space such that the cooling block is located.

Further, the trap box may include: a main box having a rear surface facing the second lateral portion and lateral surfaces extending from the rear surface, and having a front surface facing the rear surface and opened; a front cover for covering the open front surface of the main box, and the main box may further include a plurality of partition walls protruding from the rear surface toward the front cover such that a passage for gas to pass through is formed in a zigzag form.

Further, the front cover may be provided with blocking surfaces on an inner surface for preventing bypass between the passages, and the partition wall may have one end fitted into a groove between the blocking surfaces.

Further, the front cover may be secured to a top flange of the main box by a first fastening bolt, and the cooling block may be secured to a bottom flange of the main box by a second fastening bolt.

Further, the cooling unit may have a transfer plate, which has a cooling flow path with a refrigerant flowing therein, and transfers the substrate between the bake plate and an external transfer device, and the trap box may be provided with a passage through which gas is passes in a zigzag form by partition walls, and the passage may be provided with cooling pins connected with the cooling block.

Another exemplary embodiment of the present invention provides a substrate treating apparatus including: a treating unit for heat treating a substrate; and an equipment frame in which the treating unit is stacked in multiple stages and which provides a utility space to which an operator is accessible on an exterior side and a frame cover for opening and closing the utility space, in which the treating unit includes: a housing having a first lateral portion having an entrance opening through which substrate enters and exits and a second lateral portion that is in contact with the utility space; a heating unit positioned within the housing to be adjacent the second lateral portion and including a bake plate heating the substrate; and a capture module installed in the second lateral portion that is in contact with the utility space, and for capturing fumes contained in gas exhausted from the heating unit.

Further, the bake plate may further include vacuum holes for providing vacuum pressure received through a vacuum pressure line to a bottom surface of the substrate, and the capture module may include: a trap box connected to the vacuum pressure line, and for capturing fumes in gas exhausted through the vacuum pressure line; and a cooling block provided on one surface of the trap box.

Further, the treating unit may further include a transfer plate which is located within the housing, has a cooling flow path with a refrigerant flowing therein, and transfers the substrate between the bake plate and a transfer device, and the cooling block may receive a refrigerant used to cool the substrate in the transfer plate to cool the gas passing through the trap box.

Further, the capture module may further include a heat blocking member for blocking cold energy from the cooling block from being transferred to the heating unit.

Further, the heat blocking member may be located between the cooling block and the second lateral portion, and may be spaced apart from the second lateral portion, and the second lateral portion may have a recessed space such that the cooling block is located.

Further, the trap box may include: a main box having a rear surface facing the second lateral portion and lateral surfaces extending from the rear surface, and having a front surface facing the rear surface; and a front cover for covering the open front surface of the main box, and the main box may further include a plurality of partition walls protruding from the rear surface toward the front cover such that a passage for gas to pass through is formed in a zigzag form.

Further, the front cover may be provided with blocking surfaces on an inner surface for preventing bypass between the passages, and the partition wall may have one end fitted into a groove between the blocking surfaces, the trap box may be provided with cooling pins connected with the cooling block on the passage, and the cooling pins may be replaceable from the capture box.

Further, the front cover may be secured to a top flange of the main box by a first fastening bolt, and the cooling block may be secured to a bottom flange of the main box by a second fastening bolt.

Still another exemplary embodiment of the present invention provides a substrate treating apparatus including: a treating unit for heat treating a substrate; and an equipment frame in which the treating unit is stacked in multiple stages and providing a utility space to which an operator is accessible on an exterior side and a frame cover for opening and closing the utility space, in which the treating unit may include: a housing having a first lateral portion having an entrance opening through which substrate enters and exits and a second lateral portion that is in contact with the utility space; a bake plate located within the housing to be adjacent the second lateral portion and having vacuum holes for providing vacuum pressure provided via a vacuum pressure line to a bottom surface of the substrate; a transfer plate located within the housing, having a cooling flow path with a refrigerant flowing therein, and transferring the substrate between the bake plate and a transfer device; a trap module installed in the second lateral portion that is in contact with the utility space, and the trap module includes: a trap box connected to the vacuum pressure line to capture fumes in gas exhausted through the vacuum pressure line; a cooling block provided on one surface of the trap box; and a heat blocking member for blocking cold energy from the cooling block from being transferred to the bake plate.

Further, the cooling block may receive a refrigerant used to cool the substrate in the transfer plate to cool the trap box.

Further, the trap box may include: a main box having a rear surface facing the second lateral portion and lateral surfaces extending from the rear surface, and having a front surface facing the rear surface; and a front cover for covering the open front surface of the main box, and the main box further includes a plurality of partition walls protruding from the rear surface toward the front cover such that a passage for gas to pass through is formed in a zigzag form, and the front cover is provided with blocking surfaces on an inner surface for preventing bypass between the passages, and the partition wall has one end fitted into a groove between the blocking surfaces.

According to the exemplary embodiment of the present invention, by modularizing and installing the capture module, the cooling block, and the insulation member in the front portion of the heat treating apparatus that is in contact with the utility space, maintenance and repair of the capture module is possible immediately by opening and flipping the frame cover that opens and closes the utility space, thereby reducing the time required for maintenance and repair of the capture module and simplifying maintenance and repair work.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an applying block in the substrate treating apparatus of FIG. 1.

FIG. 4 is a top plan view of a developing block in the substrate treating apparatus of FIG. 1.

FIG. 5 is a top plan view schematically illustrating a transfer robot of FIG. 3.

FIG. 6 is a cross-sectional view schematically illustrating one example of a liquid treating chamber of FIG. 3 or FIG. 4.

FIG. 7 is a top plan view schematically illustrating one example of the heat treating chamber of FIG. 3 or FIG. 4.

FIG. 8 is a cross-sectional view of the heat treating chamber of FIG. 7.

FIG. 9 is a block diagram illustrating a capture module connected with a vacuum pressure supply line and a refrigerant discharge line.

FIG. 10 is a perspective view illustrating substrate heat-treating apparatuses stacked and arranged on an equipment frame.

FIG. 11 is a diagram illustrating the state where a cover of the equipment frame is removed for maintenance and repair of the substrate heat-treating apparatus.

FIG. 12 is a perspective view illustrating the capture module.

FIG. 13 is a cross-sectional view of the capture module shown in FIG. 12.

FIG. 14 is a front view illustrating the interior of a trap box of the capture module.

FIG. 15 is a diagram illustrating a cover of the trap box.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

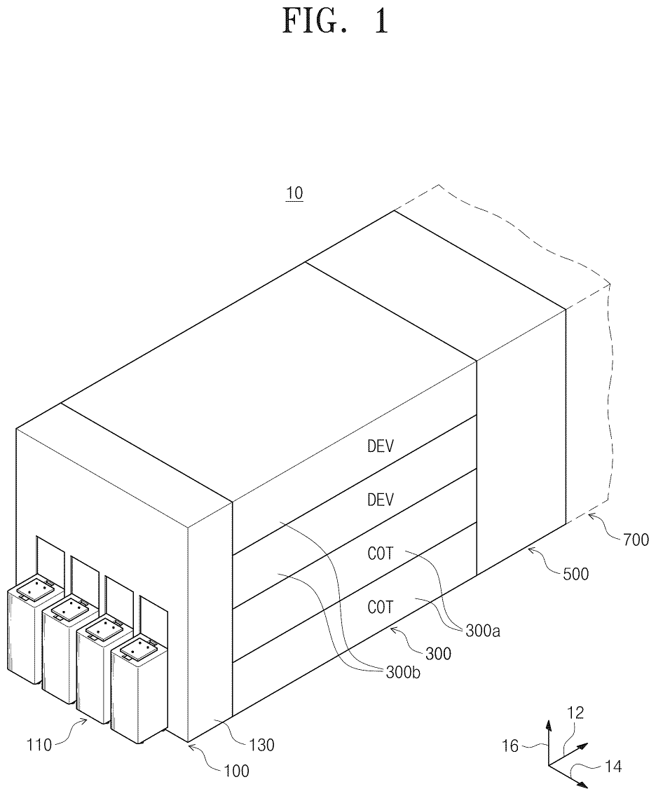

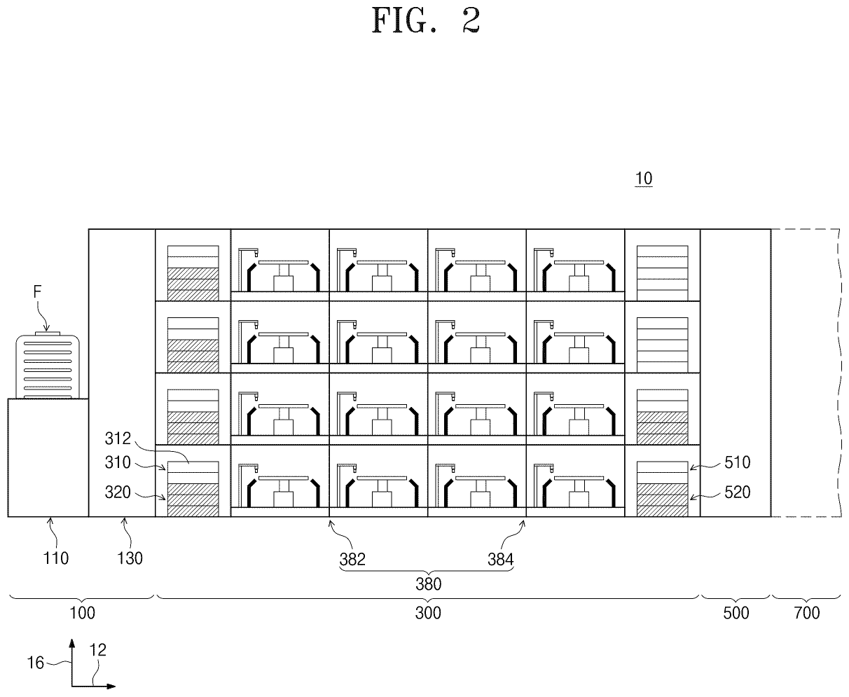

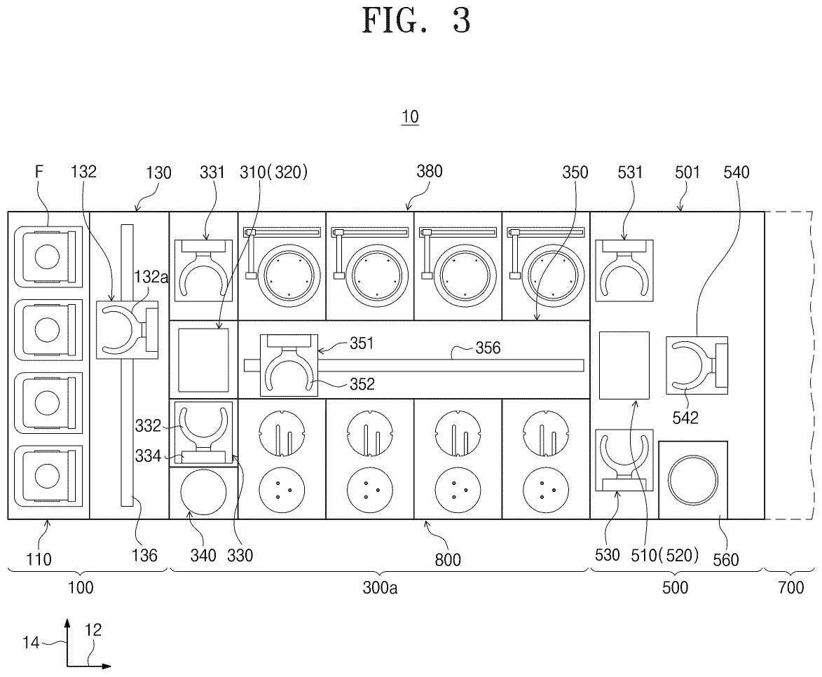

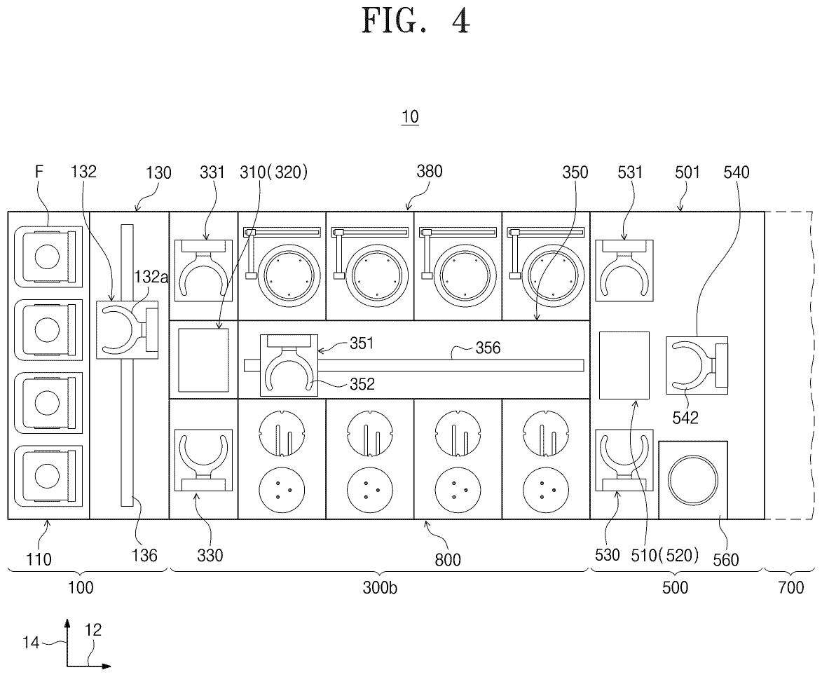

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an applying block in the substrate treating apparatus of FIG. 1, and FIG. 4 is a top plan view of a developing block in the substrate treating apparatus of FIG. 1.

Referring to FIGS. 1 to 4, a substrate treating apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the treating module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 with respect to the index frame 130. A plurality of load ports 110 may be provided, and the plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16.

The treating module 300 performs an application process and a development process on the substrate W. The treating module 300 includes an applying block 300a and a developing block 300b.

The applying block 300a performs an application process on the substrate W before the exposure process. The developing block 300b performs a development process on the substrate W after the exposure process. A plurality of applying blocks 300a is provided. The plurality of applying blocks 300a may be provided while being stacked on top of each other. A plurality of developing blocks 300b is provided. The plurality of developing blocks 300b may be provided to be stacked with each other. In one example, two applying blocks 300a are provided and two developing blocks 300b are provided. The plurality of applying blocks 300a may be located below the developing blocks 300b.

In one example, the plurality of applying blocks 300a may be provided with structures that are identical to each other. A film applied to the substrate W in each of the plurality of applying blocks 300a may be the same type of film. Optionally, the films applied to the substrate W by each applying block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with the same structures as each other. A developer supplied to the substrate W in the plurality of developing blocks 300b may be the same type of liquid. Optionally, the developer supplied to the substrate W may be different types of developer depending on the developing blocks 300b. For example, a process for removing a light-irradiated region in a region of a register film on the substrate W may be performed in one of the two developing blocks 300b, and a process for removing a non-irradiated region may be performed in the other of the two developing blocks 300b.

Referring to FIG. 3, the applying block 300a includes a buffer unit 310, a cooling unit 320, a hydrophobization chamber 340, a transfer chamber 350, a heat treating chamber 800, and a liquid treating chamber 380.

The buffer unit 310, the cooling unit 320, and the hydrophobization chamber 340 are disposed adjacent to the index block 100. The hydrophobization chamber 340 and the buffer unit 310 may be sequentially disposed along the second direction 14. In addition, the cooling unit 320 and the buffer unit 310 may be provided to be stacked on top of each other in a vertical direction.

The buffer unit 310 includes one or a plurality of buffers 312. When a plurality of buffers 312 is provided, the plurality of buffers 312 may be arranged to be stacked on top of each other. The buffer 312 provides a space for the substrate W to stay when the substrate W is transferred between the index module 100 and the treating module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forwardly and backwardly, rotatable about the third direction 16, and movable along the third direction 16. In one example, the transfer mechanism 330 is moved in the third direction 16 along a guide rail 334. The guide rail 334 extends from an applying block located at the lowest of the applying blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the applying blocks 300a and 300b provided on different layers. The transfer mechanism 330 may also transfer the substrate W between the applying block 300a and the developing block 300b.

In addition, another transfer unit 331 may be further provided on the opposite side of the side where the hydrophobization chamber 340 is provided with respect to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided so that a longitudinal direction thereof is parallel to the first direction 12. One end of the transfer chamber 350 may be located adjacent to the buffer unit 310 and/or the cooling unit 320. The other end of the transfer chamber 350 may be located adjacent to the interface module 500.

A plurality of heat treating chambers 800 is provided. Some of the heat treating chambers 800 is disposed along the first direction 12. Additionally, some of the heat treating chambers 800 may be stacked along the third direction 16. The heat treating chambers 800 may all be located on one side of the transfer chamber 350.

The liquid treating chamber 380 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 380 is provided. The liquid treating chambers 380 may be located on opposite sides of the heat treating chamber 800. For example, all of the liquid treating chambers 380 may be located on the other side of the transfer chamber 350. The liquid treating chambers 380 are arranged side-by-side along the first direction 12. Optionally, some of the liquid treating chambers 800 may be stacked along the third direction 16.

In one example, the liquid treating chambers 380 include a front end liquid treating chamber 382 and a rear end liquid treating chamber 384. The front end liquid treating chamber 382 is disposed relatively close to the index module 100, and the rear end liquid treating chamber 384 is disposed more close to the interface module 500.

The front end liquid treating chamber 382 applies a first liquid onto the substrate W, and the rear end liquid treating chamber 384 applies a second liquid onto the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

Referring to FIG. 4, the developing block 300b includes a buffer unit 310, a cooling unit 320, a transfer chamber 350, a heat treating chamber 800, and a liquid treating chamber 380. The arrangement of the buffer unit 310, the cooling unit 320, the transfer chamber 350, the heat treating chamber 800, and the liquid treating chamber 380 in the developing block 300b may be the same as the arrangement of the buffer unit 310, the cooling unit 320, the transfer chamber 350, the heat treating chamber 800, and the liquid treating chamber 380 in the applying block 300a. When viewed from above, the buffer unit 310, the cooling unit 320, the transfer chamber 350, the heat treating chamber 800, and the liquid treating chamber 380 in the developing block 300b and the buffer unit 310, the cooling unit 320, the transfer chamber 350, the heat treating chamber 800, and the liquid treating chamber 380 in the applying block 300 may be disposed in overlapping positions.

The heat treating chamber 800 performs a heating process on the substrate W. The heating process includes a post-exposure baking process performed on the substrate W after the exposure process is completed, and a hard baking process performed on the substrate W after the development process is completed.

The liquid treating chamber performs the development process by supplying a developer onto the substrate W and developing the substrate W.

In FIG. 3 or FIG. 4, the transfer chamber 350 is provided with the transfer robot 351. The transfer robot 351 transfers the substrate W between the buffer unit 310, the cooling unit 320, the heat treating chamber 800, the liquid treating chamber 380, and the buffer unit 510 or the cooling unit 520 of the interface module 500. In one example, the transfer robot 351 includes a hand 352 on which the substrate W is placed. The hand 352 may be provided to be movable forwardly and backwardly, rotatable about the third direction 16, and movable along the third direction 16. A guide rail 356, of which a longitudinal direction is parallel to the first direction 12, is provided within the transfer chamber 350, and the transfer robot 351 may be provided to be movable on the guide rail 356.

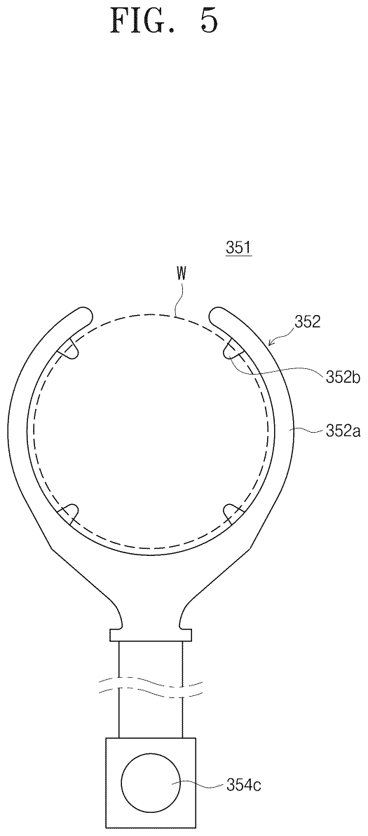

FIG. 5 is a diagram illustrating one example of a hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

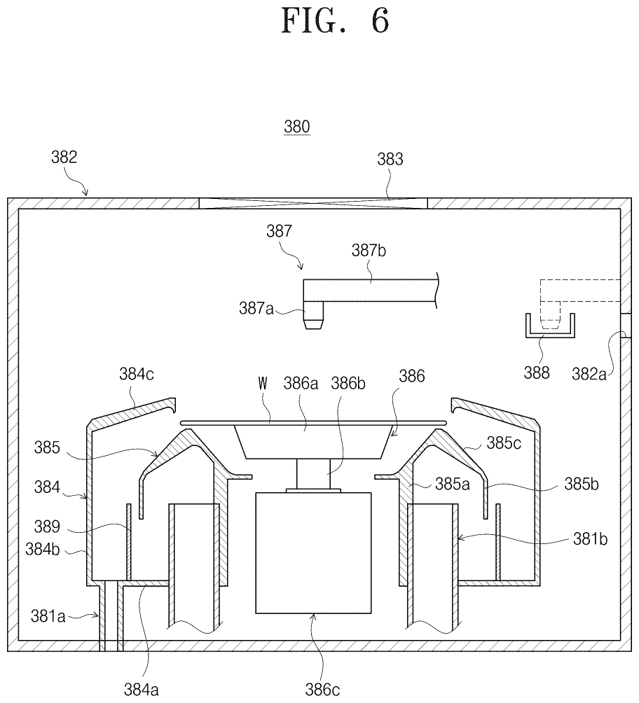

FIG. 6 is a front view schematically illustrating the liquid treating chamber of FIG. 3 or FIG. 4.

Referring to FIG. 6, the liquid treating chamber 380 includes a housing 382, an outer cup 384, a support unit 386, and a liquid supply unit 387.

The housing 382 is provided in a rectangular cylindrical shape having an inner space. An opening 382a is formed in one side of the housing 382. The opening 382a functions as a passage through which the substrate W enters and exits. A door (not illustrated) is installed in the opening 382a, and the door opens and closes the opening.

An inner space of the housing 382 is provided with the outer cup 384. The outer cup 384 has a treatment space with an open top.

The support unit 386 supports the substrate W within the treatment space of the outer cup 384. The support unit 386 includes has a support plate 386a, a rotation shaft 386b, and a driver 386c. The support plate 386a is provided with a circular top surface. The support plate 386a has a diameter smaller than the substrate W. The support plate 386a is provided to support the substrate W by vacuum pressure. The rotation shaft 386b is coupled to the center of the lower surface of the support plate 386a, and the driver 386c is provided on the rotation shaft 386b to provide rotational force to the rotation shaft 386b. The driver 386c may be a motor. Additionally, a lifting driver (not illustrated) may be provided to adjust the relative height of the support plate 386a and the outer cup 384.

The liquid supply unit 387 supplies the treatment solution onto the substrate W. When the liquid treating chamber 380 is provided in the applying block 300a, the treatment solution may be a liquid for forming a photoresist film, an anti-reflective film, or a protective film. When the liquid treating chamber 380 is provided in the developing block 300b, the treatment solution may be a developer liquid. The liquid supply unit 387 has a nozzle 387a, a nozzle support 387b, and a liquid supply source (not illustrated). The nozzle 387a discharges the treatment solution onto the substrate W. The nozzle 387a is supported on a nozzle support 387b. The nozzle support 387b moves the nozzle 387a between a process position and a standby position In the process position, the nozzle 387a supplies the treatment solution to the substrate W placed on the support plate 386a, and after completing the supply of the treatment solution, the nozzle 387a waits in the standby position. In the standby position, the nozzle 387a waits at a groove port 388, the groove port 388 is located on the outside of the outer cup 384 within the housing 382.

On the top wall of the housing 382, a fan filter unit 383 is disposed to supply a downward airflow to the inner space. The fan filter unit 383 includes a fan that introduces air from the outside into the inner space and a filter that filters the air from the outside.

The outer cup 384 includes a bottom wall 384a, a lateral wall 384b, and a top wall 384c. The inner portion of the outer cup 384 is provided as the inner space described above. The inner space H includes a treatment space at the top and an exhaust space at the bottom.

The bottom wall 384a is provided in a circular shape and has an opening in the center. The lateral wall 384b extends upwardly from the outer end of the bottom wall 384a. The lateral wall 384b is provided in a ring shape and is provided vertical to the bottom wall 384a. In one example, the lateral wall 384b extends to a height equal to the top surface of the support plate 386a, or extends to a height slightly lower than the top surface of the support plate 386a. The top wall 384c has a ring shape, with an opening in the center. The top wall 384c is provided with an upward slope from the top end of the lateral wall 384b toward the center axis of the outer cup 384.

The guide cup 385 is located on the inner side of the outer cup 384. The guide cup 385 has an inner wall 385a, an outer wall 385b, and a top wall 385c. The inner wall 385a has a through-hole that is perforated in the vertical direction. The inner wall 385a is arranged to surround the driver 386c. The inner wall 385a minimizes the exposure of the driver 386c to the airflow 84 in the treatment space. The rotational shaft 386b and/or the driver 386c of the support unit 386 extend in the vertical direction through the through-hole. The outer wall 385b is spaced apart from the inner wall 385a and is disposed to surround the inner wall 385a. The outer wall 385b is spaced apart from the lateral wall 384b of the outer cup 384. The inner wall 385a is spaced upwardly from the bottom wall 384a of the outer cup 384. The top wall 385c connects the upper end of the outer wall 385b with the upper end of the inner wall 385a. The top wall 385c has a ring shape and is disposed to surround the support plate 386a. In one example, the top wall 385c has an upwardly convex shape.

The space below the support plate 386a in the treatment space may be provided as an exhaust space. In one example, the exhaust space may be defined by the guide cup 385. The space surrounded by the outer wall 385b, the top wall 385c, and the inner wall 385a of the guide cup 385 and/or the space below the space may be provided as the exhaust space.

The outer cup 384 may be provided with a gas-liquid separation plate 389. The gas-liquid separation plate 389 may be provided to extend upwardly from the bottom wall 384a of the outer cup 384. The gas-liquid separation plate 1230 may be provided in a ring shape. The gas-liquid separation plate 389 may be located between the lateral wall 384b of the outer cup 384 and the outer wall 385b of the guide cup 385 when viewed from above. The top end of the gas-liquid separation plate 389 may be located lower than the bottom end of the outer wall 385b of the guide cup 385.

The bottom wall 384a of the outer cup 384 is connected to an outlet pipe 381a for discharging the treatment liquid and an exhaust pipe 381b. The outlet pipe 381a may be connected to the outer cup 384 from the outer side of the gas-liquid separation plate 389. The exhaust pipe 381b may be connected to the outer cup 384 from an inner side of the gas-liquid separation plate 389.

Referring again to FIGS. 1 to 4, the interface module 500 connects the treating module 300 with an external exposure device 700. The interface module 500 includes an interface frame 501, a buffer unit 510, a cooling unit 520, a transfer mechanism 530, an interface robot 540, and an additional process chamber 560.

The top end of the interface frame 501 may be provided with a fan filter unit forming a downward airflow therein. The buffer unit 510, the cooling unit 520, the transfer mechanism 530, the interface robot 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the treating module 300. The buffer unit 510 and the cooling unit 520 are disposed adjacent to the end of the transfer chamber 350. The substrate W transferred between the treating module 300, the cooling unit 520, the additional process chamber 560, and the exposure device 700 may temporarily stay in the buffer unit 510. The cooling unit 520 may be provided only at a height corresponding to the application block 300a between the application block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the treating module 300. Another transfer mechanism 531 may be further provided in a region opposite the region where the transfer mechanism 530 is provided with respect to the buffer unit 510.

The interface robot 540 is disposed between the buffer unit 510 and the exposure device 700. The interface unit 540 is provided to transfer the substrate W between the buffer unit 510, the cooling unit 520, the additional process chamber 560, and the exposure device 700. The interface robot 540 includes a hand 542 on which the substrate W is placed, and the hand 542 may be provided to be movable forwardly and backwardly, rotatable about the third direction 16, and movable along the third direction 16.

The additional process chamber 560 may perform a predetermined additional process before the substrate W processed in the applying block 300a is loaded to the exposure device 700. Optionally, the additional process chamber 560 may perform a predetermined additional process before the substrate W processed in the exposure device 700 is loaded to the developing block 300b. In one example, the additional process may be an edge exposure process that exposes an edge region of the substrate W, or a top surface cleaning process that cleans the top surface of the substrate W, or a bottom surface cleaning process that cleans the bottom surface of the substrate W, or an inspection process that performs a predetermined inspection on the substrate W. A plurality of additional process chambers 560 may be provided, which may be stacked on top of each other.

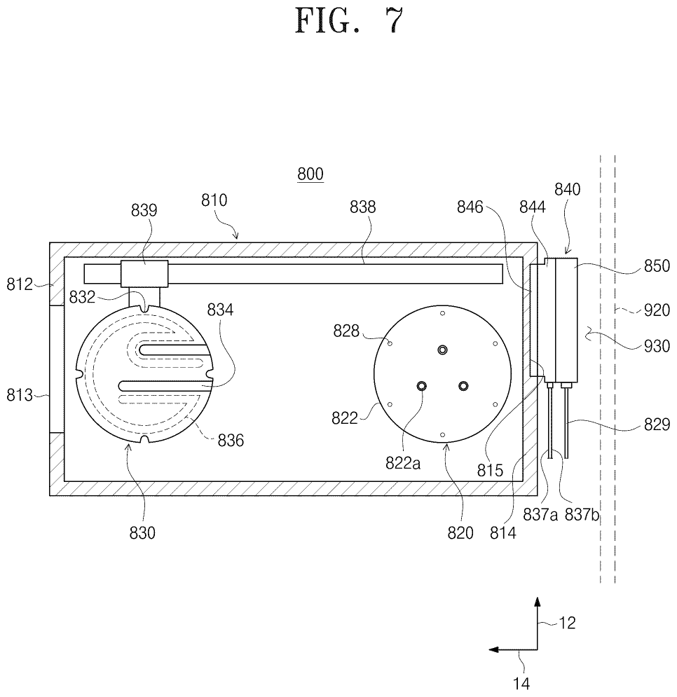

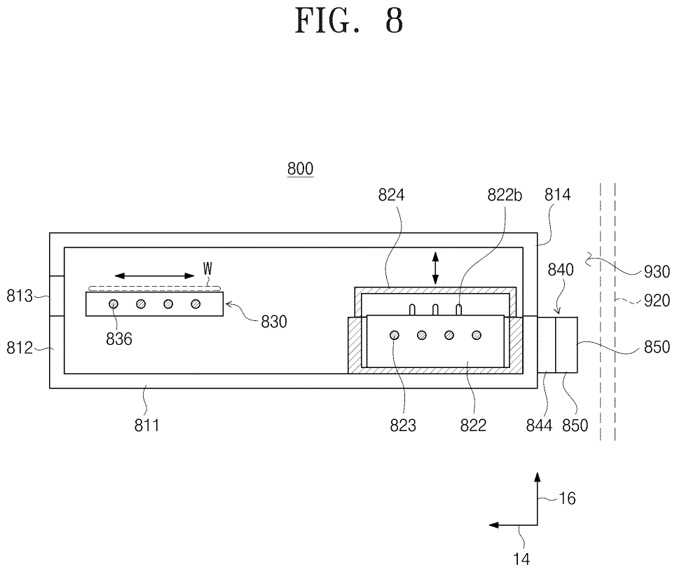

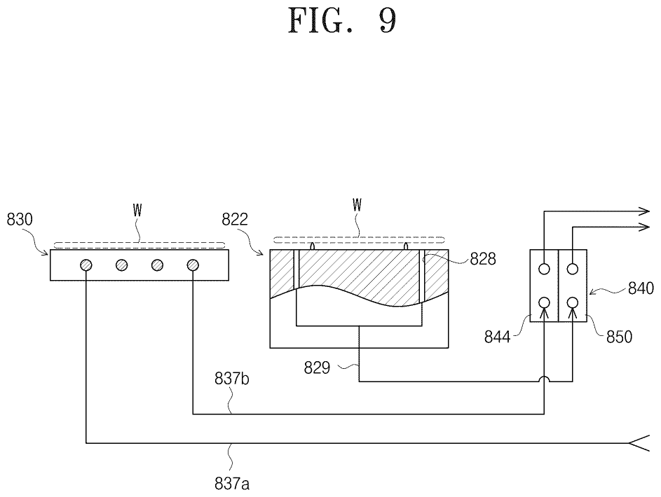

FIG. 7 is a top plan view schematically illustrating one example of the heat treating chamber of FIG. 3 or FIG. 4, FIG. 8 is a cross-sectional view of the heat treating chamber of FIG. 7, and FIG. 9 is a block diagram illustrating a capture module connected with a vacuum pressure supply line and a refrigerant discharge line. In the following, the heat treating chamber is described as a substrate heat treating apparatus. For reference, in FIG. 7, the cover of the heating unit is omitted for illustrative convenience.

Referring to FIGS. 7 to 9, the substrate heat treatment apparatus 800 can include a housing 810, a heating unit 820, a transfer plate 830, and a capture module 840.

The housing 810 may include a bottom surface 811, a first lateral portion 812, and a second lateral portion 814. The first lateral portion 812 may be provided with an entrance opening 813 through which the substrate W enters and exits. The entrance opening 813 may be maintained in an open state. Optionally, a door (not illustrated) may be provided to open and close the entrance opening. The heating unit 820 and the transfer plate 830 may be provided within the housing 810. The second lateral portion 814 may be located to be in contact with a utility space.

The heating unit 820 may be provided adjacent to the second lateral portion. The heating unit 820 may include a bake plate 822 and a cover 824.

The bake plate 822 has a substantially circular shape when viewed from the top. The bake plate 822 has a diameter that is larger than the substrate W. The bake plate 822 transfers heat generated by the heater 823 to the substrate W. In one example, the heaters 823 may be printed patterns or heating wires that are heated by the supply of electrical power. The bake plate 822 may be provided in the shape of a circular plate. The top surface of the bake plate 822 has a larger diameter than the substrate. The top surface of the bake plate 822 functions as a seating surface on which the substrate W is placed. A plurality of lift holes 822a, vacuum holes 828, and proximate pins (not shown) are formed on the seating surface. The lift holes 822a and the vacuum holes 828 are located in different regions. Each of the lift holes 822a may be spaced apart from each other along the circumferential direction. A lift pin 822b may be located in each lift hole 822a. The lift pins 822b may be provided to be movable in an upward and downward direction along the third direction 16. The lift pin 822b may receive the substrate W from the transfer plate 830 and place the substrate W down on the bake plate 822, or lift the substrate W from the bake plate 822 and transfer the substrate to the transfer plate 830. In one example, three lift pins 822b may be provided.

The vacuum holes 828 can provide negative pressure between the seating surface and the edge of the substrate W. The warpage substrate can be flattened and secured to the bake plate 822 by the negative pressure provided through the vacuum holes 828. In one example, the vacuum holes 828 may be evenly arranged in an edge region of the seating surface. The vacuum holes 828 are connected to a vacuum pressure supply line 829. The vacuum pressure supply line 829 provides vacuum pressure to the vacuum holes 828. The vacuum pressure supply line 829 is connected to the capture module.

The cover 824 has a lower open space inside. The cover 824 is located on top of the bake plate 822 and is moved in an up and down direction by a driver (not shown). The space formed by the cover 824 and the bake plate 822 according to the movement of the cover 824 is provided as a heating space for heating the substrate W.

The transfer plate 830 is provided in a substantially disk shape, and has a diameter corresponding to that of the substrate W. A notch 830 is formed at the edge of the transfer plate 832. The notch 832 may have a shape that corresponds to the protrusion 352b formed on the hand of the transfer robot 352 described above. Further, the notches 832 are provided in a number corresponding to the protrusions 352b formed on the hand, and are formed at positions corresponding to the protrusions 352b. In a position in which the hand and the transfer plate 830 are arranged in the vertical direction, the substrate W is transferred between the hand 354 and the transfer plate 830 when the vertical position of the hand and the transfer plate 830 is changed. The transfer plate 830 may be mounted on a guide rail 838 and may be moved along the guide rail 838 by the driver 839.

A plurality of slit-shaped guide grooves 830 is provided in the transfer plate 834. The guide groove 834 extends from the distal end of the transfer plate 830 to the inside of the transfer plate 830. The longitudinal direction of the guide groove 834 is provided along the second direction 14, and the guide grooves 834 are spaced apart from each other along the first direction 12. The guide groove 834 prevents the transfer plate 830 and the lift pin 822c from interfering with each other when a handover of the substrate W occurs between the transfer plate 830 and the heating unit 820.

The transfer plate 830 is provided of a thermally conductive material. According to an example, the transfer plate 830 may be made of a metal material.

A cooling flow path 830 is formed in the transfer plate 836. The cooling passage 836 is connected to the refrigerant supply line 837a, and the cooling passage 836 is supplied with coolant via the refrigerant supply line 837a. The substrate W, which has been completely heated in the heating unit 820, may be cooled while being transferred by the transfer plate 830. That is, the transfer plate 830 may function as a cooling unit to cool the substrate. Additionally, the substrate W may be cooled on the transfer plate 830 while waiting on the transfer plate 830 to be transferred to the transfer robot 351. The coolant used to cool the substrate in the transfer plate 830 is discharged through the refrigerant discharge line 837b. The refrigerant discharge line 837b is connected to the capture module 840.

Although not shown, optionally, a cooling unit may additionally be provided within the housing 810. In this case, the cooling unit may be arranged in parallel with the heating unit 810. The cooling unit may be provided as a cooling plate having a passage formed therein through which coolant flows. The substrate that has been heated in the heating unit may be returned to the cooling unit for cooling.

The capture module 840 may be installed on the second lateral portion 814 of the housing 810 that abuts a utility space 930. Specifically, the capture module 840 may be located between the second lateral portion 814 of the housing and the frame cover 920. The capture module 840 is provided to capture fumes contained in the gas exhausted from the heating unit 820.

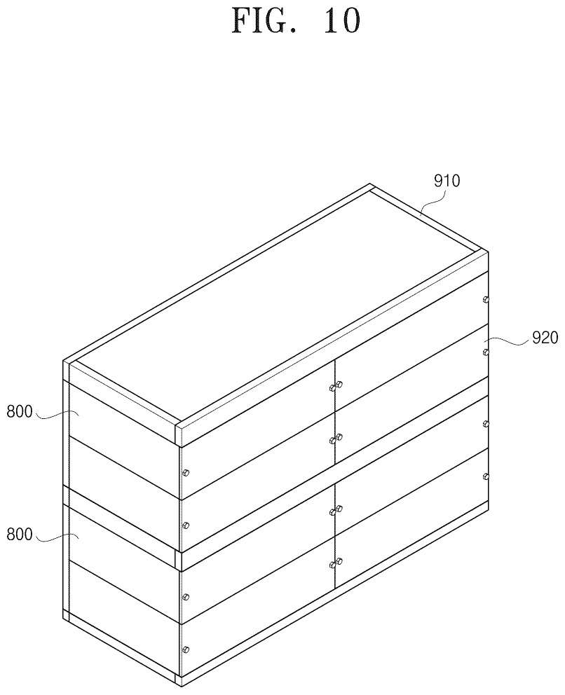

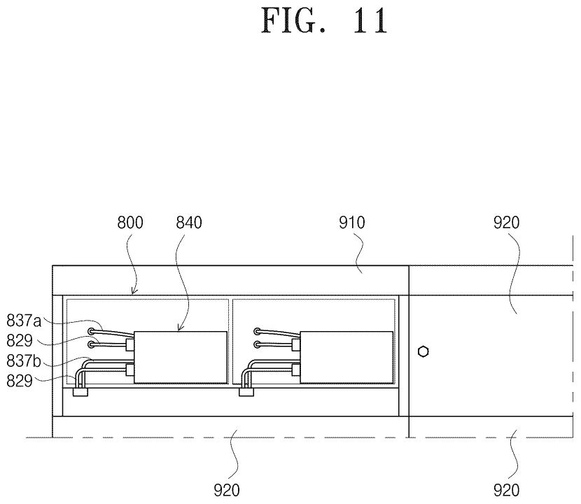

FIG. 10 is a perspective view illustrating substrate heat-treating apparatuses stacked and arranged on an equipment frame, and FIG. 11 is a diagram illustrating the state where a cover of the equipment frame is removed for maintenance and repair of the substrate heat-treating apparatus.

The substrate heat treatment apparatuses 800 may be stacked and disposed in an equipment frame 910. The equipment frame 910 may be provided with a utility space 930 between the substrate heat-treating apparatus 800 and an outer surface. The utility space 930 is a space to which an operator is accessible for maintenance and repair of the substrate heat treatment apparatus 800. Although not shown, in the utility space 930, various pipes (vacuum pressure supply lines, refrigerant supply lines, refrigerant discharge lines, main ducts, and the like) and cables that connect to the substrate heat treatment apparatus 800 may be located. The exterior of the equipment frame 910 may be provided with a frame cover 920 that opens and closes the utility space 930. When the frame cover 920 is removed from the equipment frame 910, the utility space 930 opens to expose the capture module 840. Thus, an operator is capable of removing and maintaining (maintaining and repairing) the capture module 840 without disassembling the substrate heat treatment apparatus 800.

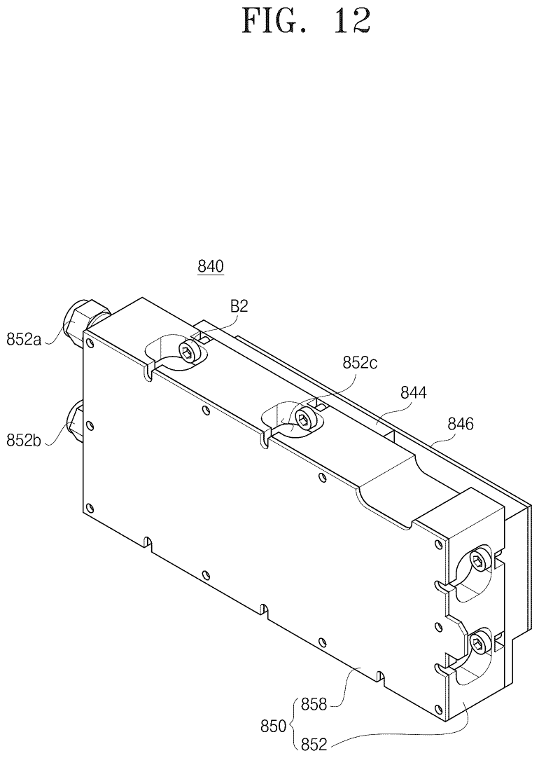

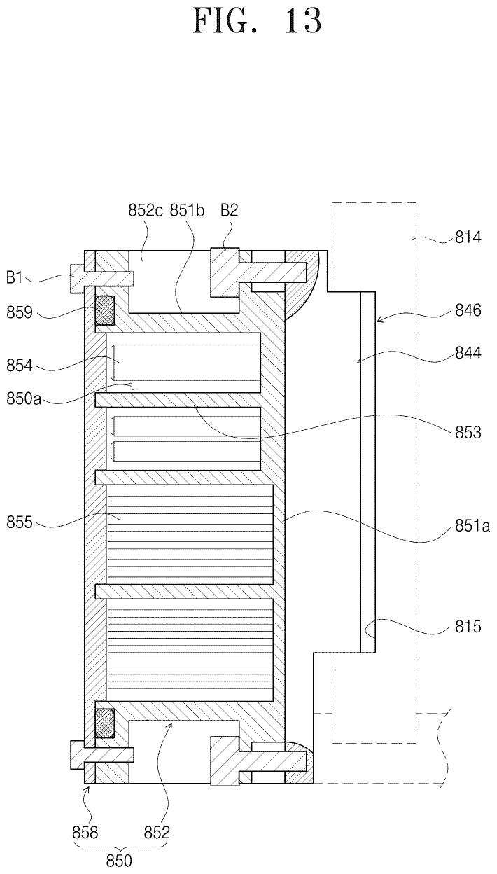

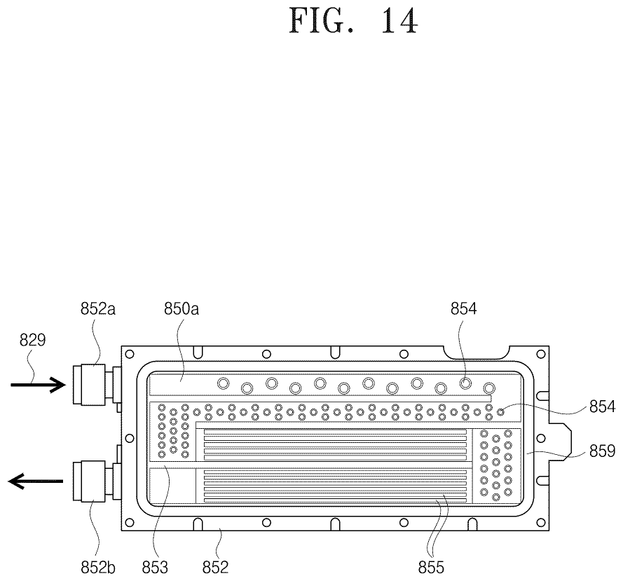

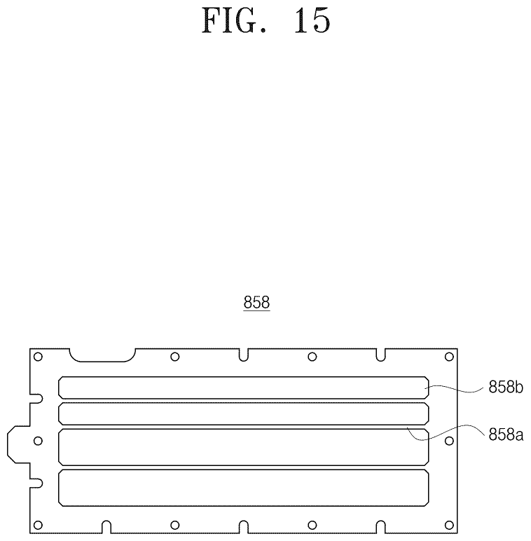

FIG. 12 is a perspective view illustrating the capture module, FIG. 13 is a cross-sectional view of the capture module shown in FIG. 12, FIG. 14 is a front view illustrating the interior of a trap box of the capture module, and FIG. 15 is a diagram illustrating a cover of the trap box.

Referring to FIGS. 12 to 15, the capture module 840 can include a trap box 850, a cooling block 844, and a heat blocking member 846. The trap box 850, the cooling block 844, and the heat blocking member 846 may be provided as a module coupled together.

The trap box 850 can include a main box 852 and a front cover 858. The main box 852 may be provided in the form of a box having a rear surface 851a facing a second lateral portion 814 of the housing 810 and lateral surfaces 851b extending from the rear surface 851a, and having an open front facing the rear surface 851a.

The main box 852 is connected to a vacuum pressure line 829. The main box 852 includes an inlet port 852a through which gas exhausted through the vacuum pressure line 829 enters and an exhaust port 852b through which gas passing through the trap box 850 is exhausted. The main box 852 has a passage 850a through which the gas passes in a zigzag form. The passage 850a may be provided by a plurality of partition walls 853 that protrude from the rear surface 851a toward the front cover 858. The passage 850a may be provided with a plurality of cooling pins 854 and cooling plates 855 of various shapes. In one example, the cooling pins 854 may be cylindrical in shape and the cooling plates 855 may be flat plate shaped. Fumes contained in the gas may be captured on the surfaces of the cooling pins 854 and the cooling plates 855 as they pass through the passage 850a.

For example, the cooling plates 855 and the cooling pins 854 may be provided to be replaceable from the main box 852 to facilitate cleaning and the like during maintenance and repair operations. In one example, the cooling plates 855 and the cooling pins 854 may be secured to the rear surface of the main box 852 in the form of a push fit.

The front cover 858 is provided to seal the open front surface of the main box 852, and an O-ring 859 is installed on the front flange of the main box 852 with which the front cover 858 is in contact. The front cover 858 may be secured to the front flange of the main box 852 by first fastening bolts B1. The front cover 858 may be provided with convex surfaces 858b on the inner surface for preventing bypass between the passages 850a. Between the convex surfaces 858b is provided a slotted groove 858a, and the partition wall 853 is fitted into the groove 858a.

The cooling block 844 may be provided to be in surface contact with the rear surface of the main box 852. The cooling block 844 may be secured to the bottom flange of the main box 852 by a second fastening bolt B2. The main box 852 may have bolt recesses 852c formed in the lateral surface thereof to facilitate securing the cooling block 844 with the second fastening bolt B2.

The cooling block 844 receives a refrigerant (coolant) used for cooling the substrate from the transfer plate 830 to reduce the temperature of the trap box. The cooling block 844 is connected to the refrigerant discharge line 837b, which is connected to the transfer plate 830. As such, the cooling block 844 utilizes the refrigerant used in the transfer plate 830, eliminating the need to additionally install a separate refrigerant supply line.

The heat blocking member 846 is provided to block cold energy from the cooling block 844 from being transferred to the heating unit 920. The heat blocking member may be an insulating plate. The insulating plate may be located between the cooling block and the housing. The second lateral portion 814 of the housing may provide a recessed space 815 for obtaining the space of the cooling block 844 and the heat blocking member 846.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A substrate heat-treating apparatus comprising:
a housing having a first lateral portion and a second lateral portion facing the first lateral portion;
a heating unit located adjacent the second lateral portion and including a bake plate heating a substrate; and
a capture module installed in the second lateral portion and for capturing fumes contained in gas exhausted from the heating unit.

2. The substrate heat-treating apparatus of claim 1, wherein the bake plate further includes vacuum holes for providing vacuum pressure received through a vacuum pressure line to a bottom surface of the substrate, and
the capture module includes:
a trap box connected to the vacuum pressure line, and for capturing fumes in gas exhausted through the vacuum pressure line; and
a cooling block provided on one surface of the trap box, and
the second lateral portion is located opposite a frame cover for maintenance and repair, and the capture module is located between the second lateral portion and the frame cover.

3. The substrate heat-treating apparatus of claim 2, further comprising:
a cooling unit located within the housing and for cooling the substrate by using a refrigerant,
wherein the cooling block receives a refrigerant used to cool the substrate in the cooling unit to cool gas passing through the trap box.

4. The substrate heat-treating apparatus of claim 2, wherein the capture module further includes a heat blocking member for blocking cold energy from the cooling block from being transferred to the heating unit.

5. The substrate heat-treating apparatus of claim 4, wherein the heat blocking member is located between the cooling block and the second lateral portion, and is spaced apart from the second lateral portion, and
the second lateral portion has a recessed space such that the cooling block is located.

6. The substrate heat-treating apparatus of claim 2, wherein the trap box includes:
a main box having a rear surface facing the second lateral portion and lateral surfaces extending from the rear surface, and having a front surface facing the rear surface and opened;
a front cover for covering the open front surface of the main box, and
the main box further includes a plurality of partition walls protruding from the rear surface toward the front cover such that a passage for gas to pass through is formed in a zigzag form.

7. The substrate heat-treating apparatus of claim 6, wherein the front cover is provided with blocking surfaces on an inner surface for preventing bypass between the passages, and
the partition wall has one end fitted into a groove between the blocking surfaces.

8. The substrate heat-treating apparatus of claim 6, wherein the front cover is secured to a top flange of the main box by a first fastening bolt, and
the cooling block is secured to a bottom flange of the main box by a second fastening bolt.

9. The substrate heat-treating apparatus of claim 3, wherein the cooling unit has a transfer plate, which has a cooling flow path with a refrigerant flowing therein, and transfers the substrate between the bake plate and an external transfer device, and
the trap box is provided with a passage through which gas is passes in a zigzag form by partition walls, and
the passage is provided with cooling pins connected with the cooling block.

10. A substrate treating apparatus comprising:
a treating unit for heat treating a substrate; and
an equipment frame in which the treating unit is stacked in multiple stages and which provides a utility space to which an operator is accessible on an exterior side and a frame cover for opening and closing the utility space,
wherein the treating unit includes:
a housing having a first lateral portion having an entrance opening through which substrate enters and exits and a second lateral portion that is in contact with the utility space;
a heating unit positioned within the housing to be adjacent the second lateral portion and including a bake plate heating the substrate; and
a capture module installed in the second lateral portion that is in contact with the utility space, and for capturing fumes contained in gas exhausted from the heating unit.

11. The substrate treating apparatus of claim 10, wherein the bake plate further includes vacuum holes for providing vacuum pressure received through a vacuum pressure line to a bottom surface of the substrate, and
the capture module includes:
a trap box connected to the vacuum pressure line, and for capturing fumes in gas exhausted through the vacuum pressure line; and
a cooling block provided on one surface of the trap box.

12. The substrate treating apparatus of claim 11, wherein the treating unit further includes a transfer plate which is located within the housing, has a cooling flow path with a refrigerant flowing therein, and transfers the substrate between the bake plate and a transfer device, and
the cooling block receives a refrigerant used to cool the substrate in the transfer plate to cool the gas passing through the trap box.

13. The substrate treating apparatus of claim 11, wherein the capture module further includes a heat blocking member for blocking cold energy from the cooling block from being transferred to the heating unit.

14. The substrate treating apparatus of claim 13, wherein the heat blocking member is located between the cooling block and the second lateral portion, and is spaced apart from the second lateral portion, and
the second lateral portion has a recessed space such that the cooling block is located.

15. The substrate treating apparatus of claim 12, wherein the trap box includes:
a main box having a rear surface facing the second lateral portion and lateral surfaces extending from the rear surface, and having a front surface facing the rear surface; and
a front cover for covering the open front surface of the main box, and
the main box further includes a plurality of partition walls protruding from the rear surface toward the front cover such that a passage for gas to pass through is formed in a zigzag form.

16. The substrate treating apparatus of claim 15, wherein the front cover is provided with blocking surfaces on an inner surface for preventing bypass between the passages, and
the partition wall has one end fitted into a groove between the blocking surfaces,
the trap box is provided with cooling pins connected with the cooling block on the passage, and
the cooling pins are replaceable from the capture box.

17. The substrate treating apparatus of claim 15, wherein the front cover is secured to a top flange of the main box by a first fastening bolt, and
the cooling block is secured to a bottom flange of the main box by a second fastening bolt.

18. A substrate treating apparatus comprising:
a treating unit for heat treating a substrate; and
an equipment frame in which the treating unit is stacked in multiple stages and providing a utility space to which an operator is accessible on an exterior side and a frame cover for opening and closing the utility space,
wherein the treating unit includes:
a housing having a first lateral portion having an entrance opening through which substrate enters and exits and a second lateral portion that is in contact with the utility space;
a bake plate located within the housing to be adjacent the second lateral portion and having vacuum holes for providing vacuum pressure provided via a vacuum pressure line to a bottom surface of the substrate;
a transfer plate located within the housing, having a cooling flow path with a refrigerant flowing therein, and transferring the substrate between the bake plate and a transfer device;
a trap module installed in the second lateral portion that is in contact with the utility space, and
the trap module includes:
a trap box connected to the vacuum pressure line to capture fumes in gas exhausted through the vacuum pressure line;
a cooling block provided on one surface of the trap box; and
a heat blocking member for blocking cold energy from the cooling block from being transferred to the bake plate.

19. The substrate treating apparatus of claim 18, wherein the cooling block receives a refrigerant used to cool the substrate in the transfer plate to cool the trap box.

20. The substrate treating apparatus of claim 19, wherein the trap box includes:
a main box having a rear surface facing the second lateral portion and lateral surfaces extending from the rear surface, and having a front surface facing the rear surface; and
a front cover for covering the open front surface of the main box, and
the main box further includes a plurality of partition walls protruding from the rear surface toward the front cover such that a passage for gas to pass through is formed in a zigzag form, and
the front cover is provided with blocking surfaces on an inner surface for preventing bypass between the passages, and
the partition wall has one end fitted into a groove between the blocking surfaces.
